(19) United States
(12) Patent Application Publication
(10) Pub. No.: US 2018/0331532 A1
(43) Pub. Date: Nov. 15, 2018

(54) ALTERNATING-CURRENT POWER SWITCH AND METHOD FOR SWITCHING AN ALTERNATING CURRENT

(71) Applicant: SIEMENS AKTIENGESELLSCHAFT, MUENCHEN (DE)

(72) Inventors: GUENTER SACHS, HERZOGENAURACH (DE); FRANK SCHREMMER, FUERTH (DE); ANDREAS ZENKER, VEITSBRONN (DE)

(21) Appl. No.: 15/777,418

(22) PCT Filed: Dec. 14, 2015
(86) PCT No.: PCT/EP2015/079543

§ 371 Date: May 18, 2018

(51) Int. Cl. H02H 3/20; H02H 1/00; H02H 3/02; H03K 17/0814; H02M 1/08

(52) U.S. Cl. CPC H02H 3/20; H02H 1/0007; H02M 1/08; H03K 17/08148; H02H 3/025

(57) ABSTRACT

An alternating current circuit breaker has a series circuit of bipolar switching modules which are inserted in series into a phase line of an alternating current line. Each switching module has an energy storage device and actuatable power semiconductors that can be activated and deactivated. Each switching module can be driven such that a switching module voltage that corresponds to a positive or negative energy storage device voltage or a zero voltage can be generated at the poles of the switching module. A controller is configured to actuate the switching modules based on a polarity change of a phase current such that the switching module voltage switches polarity, wherein a switching module voltage opposite the phase voltage can be generated. A method for switching alternating currents is effected with the alternating current circuit breaker.

The invention relates to an alternating-current power switch.

Alternating-current power switches are employed in high-voltage installations and high-voltage lines in order to switch an operating current or a short-circuit current. Ordinarily, such an alternating-current power switch includes a gas-insulated or vacuum-insulated contact arrangement with a mechanical drive. When such a contact arrangement is opened, arcs arise, so the known alternating-current power switches usually exhibit an arc-quenching device. In addition, in the known alternating-current power switches ordinarily the switching operation is always carried out in the course of a passage through zero current. Under certain circumstances this leads to a disadvantageous delay-time, for instance between ascertaining a fault and switching the current off.

An object of the invention is to propose an alternating-current power switch that enables a fast and reliable switching of alternating currents.

This object is achieved by an alternating-current power switch that comprises a series connection of bipolar switching modules, which can be serially inserted into a phase line of an alternating-voltage line, wherein each switching module exhibits an energy-storage device and also power semiconductors that are capable of being driven and capable of being switched on and off, and is capable of being driven in such a manner that at its poles a switching-module voltage can be generated that corresponds to a positive or negative energy-storage voltage or to a voltage having the value zero, and also a control device for driving the switching modules, which has been set up to drive the switching modules in a manner depending on a reversal of polarity of a phase current in such a manner that the switching-module voltage changes its polarity, whereby a switching-module voltage opposed to a phase voltage can be generated.

With the alternating-current power switch according to the invention, an alternating-current switch using pure power electronics is made available. The alternating-current power switch according to the invention is capable of switching a current in the phase line at any time, irrespective of an instantaneous value of the current. A passage through zero current does not need to be awaited. In addition, in the course of switching by means of the alternating-current power switch according to the invention no arcs arise. The switching modules connected in series are capable of switching off very quickly, within a few microseconds. Over and above this, switching can be effected in bounce-free manner by means of the alternating-current power switch according to the invention.

The control device is capable of driving the power semiconductors independently of one another. For the purpose of switching the phase current, the control device controls the switching modules, or the power semiconductors of the switching modules, in a manner depending on a reversal of polarity of a phase current. In this process, the polarity of the switching-module voltage of each of the switching modules changes. Since the switching modules are connected to one another in a series circuit, a total voltage of the series circuit arises that corresponds to the sum of the switching-module voltages of all the switching modules. In the event of a reversal of polarity of the phase current all the switching modules are capable of being driven in such a manner that the switching-module voltage is opposed to a phase voltage. Hence by means of the alternating-current power switch according to the invention a counter-voltage directed or polarized opposite to the phase voltage to be switched can be generated that is equal to the total voltage of the series connection of the switching modules. In the event of a subsequent reversal of polarity of the phase current, the control device can once again change the switching modules in such a manner that a counter-voltage is again built up. Within the scope of the invention, however, it is not necessary for the control device to drive the switching modules precisely at the time of the reversal of polarity of the phase current in such a manner that the polarity of the switching-module voltage changes. Rather, it is also possible that some or even all of the switching modules change the polarity of their switching-module voltage with respect to the passage through zero current in time-delayed manner. The drive of the switching modules for the purpose of reversing the polarity of the switching-module voltage may, for instance, follow the alternating-current frequency in the alternating-voltage line.

If the alternating-voltage line is of polyphase design, the alternating-current power switch suitably comprises a plurality of the series connections of the switching modules, the number of which corresponds to the number of phase lines of the alternating-voltage line. Each one of the series connections is assigned to a respective phase line and capable of being inserted into it.

Over and above the advantages previously described, the alternating-current power switch according to the invention can be employed as a filter unit in the alternating-voltage line. In this case, the control device has been set up to drive the switching modules in such a manner that a fundamental oscillation and also harmonics of the voltage or of the current can be influenced by means of the alternating-voltage power switch according to the invention. Hence instabilities arising in the phase line can be damped quickly. In addition, energy can be withdrawn from certain harmonics or transient processes in the alternating-voltage network and can be fed back into the alternating-voltage network at a different, non-critical frequency. The alternating-current power switch employed as a filter unit expediently interacts with an inductor which takes the form of, for instance, a choke and is arranged in series with the series connection of the switching modules.

A suitable fault-detection device can detect a fault or a transient process in the alternating-voltage line and relay a corresponding signal to the control device. By reason of such a signal, the control device is capable of driving the switching modules to switch off the current in the phase line.

In principle, the number of switching modules of a series circuit is arbitrary. Said number has been suitably adapted to the respective application. In particular, the number of switching modules may depend on a nominal voltage and on a nominal current in the phase line.

By means of the alternating-current power switch according to the invention, a longitudinal voltage of a predetermined frequency and phase can be generated in the phase line. In this case, the energy from the alternating-voltage network is temporarily stored in the energy-storage devices of the switching modules. Therefore the apparatus is able to feed reactive power into the alternating-voltage network, whereby a short-term feed of active power is likewise possible, suitably by means of an interaction with a phase inductor.

An isolating switch may be arranged in series with the series connection of the switching modules. The isolating switch has been set up to interrupt the phase line after the current has been switched off by means of the series connection of the switching modules.

According to one embodiment of the invention, at least some of the switching modules are realized as full-bridge circuits. A full-bridge circuit is described in WO 2013/087110 A1, for instance. A full-bridge circuit exhibits two series connections, arranged in parallel, of power-semiconductor switches. The energy-storage device is connected in parallel with the series connections. The first connector or the first connecting terminal or the first pole of the switching module taking the form of a full-bridge circuit is arranged between the two power-semiconductor switches of the first series connection. The second connection of the switching module is arranged between the two power-semiconductor switches of the second series connection. The two power-semiconductor switches of the first and of the second series connection have the same forward direction. A freewheeling diode is connected antiparallel to each of the power-semiconductor switches. In the case of a charged energy-storage device at which the energy-storage voltage falls, by suitable switching of the power-semiconductor switches on and off in a manner known to a person skilled in the art a switching-module voltage at the connecting terminals of the switching module can be generated that corresponds to the positive or negative energy-storage voltage or to the zero voltage. The use of the full-bridge circuits has the advantage, in particular, that methods for driving the switching modules in this case are well known and manageable.

However, other circuits for use in the switching modules are also possible. For instance, it is possible to design the switching modules as two oppositely-directed half-bridge circuits. A half-bridge circuit is known from DE 101 03 031 B4, for instance.

The sum of the energy-storage voltages preferably amounts to more than the product of the square root of two and a nominal voltage Un of the phase line. Hence it can advantageously be ensured that the peak-value voltage in the phase line can also be reliably switched off. The maximum counter-voltage that can be generated in this case is higher than √2*Un. It is regarded as particularly advantageous if the maximum counter-voltage that can be generated is greater than a maximum operating voltage. This permits a consideration of a tolerance margin of the operating voltages, which is ordinarily predetermined by the respective network operator. Accordingly, the maximum counter-voltage that can be generated is higher than √2*Un*p, where p is a tolerance factor having a value between 1 and 1.3, for instance.

According to one embodiment of the invention, a monitoring device for monitoring the energy-storage voltages is provided which enables a balancing of the energy-storage voltages. The balancing of the energy-storage voltages serves to prevent an overvoltage at the energy-storage devices. Said balancing causes the energy storage devices to be charged and discharged uniformly.

The invention further relates to a method for switching an alternating current.

An object of the invention consists in proposing such a method that permits a switching of alternating currents that is as fast and reliable as possible.

In accordance with the invention, this object is achieved by a method for switching an alternating current by means of the alternating-current power switch according to the invention, in which the switching modules are driven in a manner depending on a reversal of polarity of a phase current in such a manner that the switching-module voltage changes its polarity, whereby a switching-module voltage opposed to a phase voltage is generated.

The advantages of the method according to the invention result from the advantages described in connection with the alternating-current power switch according to the invention.

According to one embodiment of the method, the switching modules are driven at the same time in the course of the reversal of polarity of the phase current, so that the switching-module voltage changes its polarity. Hence particularly high currents can be switched off particularly quickly.

According to a further embodiment of the method, the switching modules are driven in time-shifted manner in the course of the reversal of polarity of the phase current, so that the switching-module voltages change their polarities in time-shifted manner. Hence a counter-voltage can be increased stepwise. In this way, the current to be switched off can be limited or switched off more slowly. Accordingly, overvoltages in the phase line can be limited, and disadvantageous switching transients can be avoided.

In the case of the method according to the invention, use is preferentially made of switching modules that are realized as the full-bridge circuits already described previously.

For the purpose of balancing the energy-storage voltages, the energy-storage voltages are preferably monitored by means of a monitoring device. This makes it possible to avoid overvoltages at the energy-storage devices.

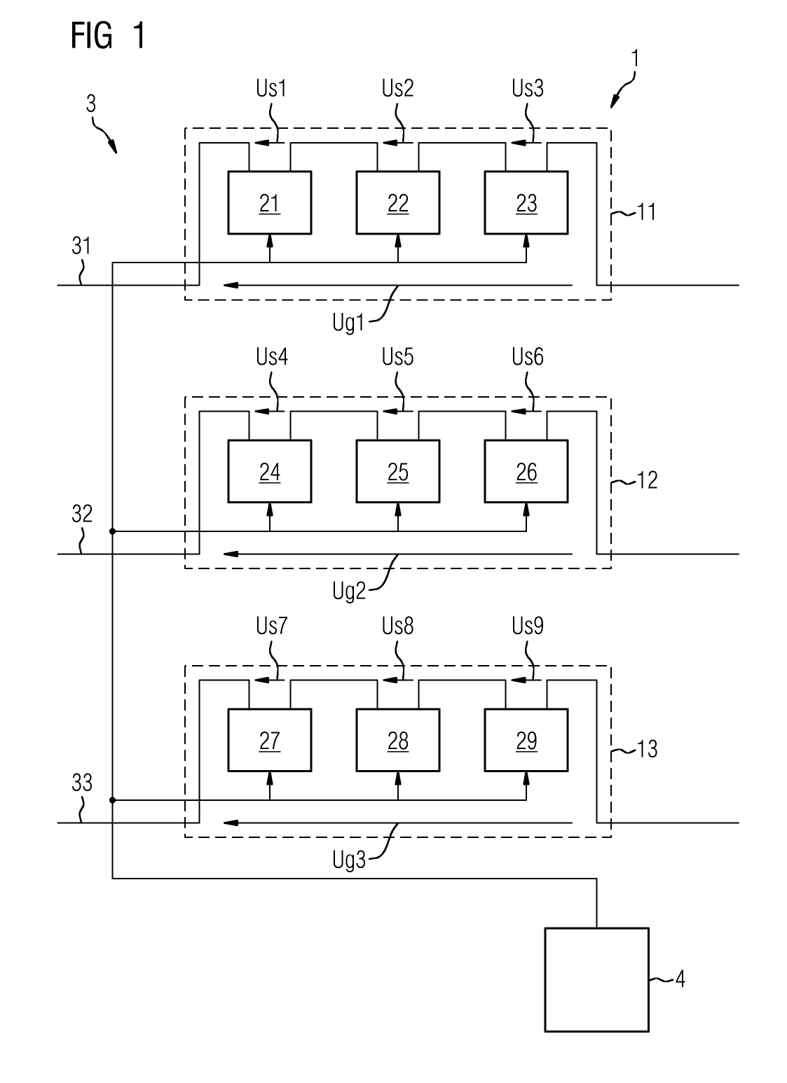

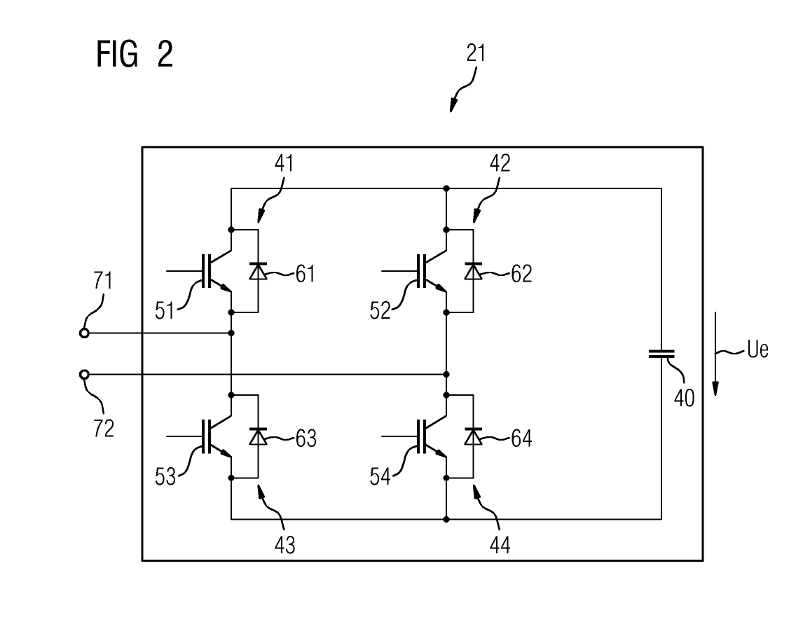

The invention will be elucidated further in the following on the basis of an embodiment example represented in FIGS. 1 and 2.

FIG. 1 shows an embodiment example of an alternating-current power switch according to the invention in schematic representation;

FIG. 2 shows a switching module for the alternating-current power switch according to the embodiment example shown in FIG. 1.

In detail, an embodiment example of an alternating-current power switch 1 is represented in FIG. 1. The alternating-current power switch 1 includes a first series connection 11 of bipolar switching modules 21, 22 and 23. The first series connection 11 has been serially inserted into a first phase line 31 of a three-phase alternating-voltage line 3.

Furthermore, the alternating-current power switch 1 includes a second series connection 12 of switching modules 24 to 26, which is arranged in a second phase line 32 of the alternating-voltage line 3, and a third series connection 13 of switching modules 27 to 29, which is arranged in a third phase line 33.

In the embodiment example represented in FIG. 1, all three series connections 11, 12 and 13 are of similar structure. All the switching modules 21-29 also exhibit the same structure. They are realized as full-bridge circuits.

At the connecting terminals of each switching module 21-29 a switching-module voltage Us1-Us9 falls. The switching-module voltages Us1-Us9 generally have differing values with differing polarities at a given time.

The sum of the switching-module voltages Us1-Us3 yields a total voltage Ug1 of the first series connection 11: Ug1=Us1+Us2+Us3.

Correspondingly, for a total voltage Ug2 of the second series connection and for a total voltage Ug3 of the third series connection it holds that Ug2=Us4+Us5+Us6 and Ug3=Us7+Us8+Us9.

By means of the switching-module voltages, a counter-voltage with respect to a phase voltage obtaining in the respective phase line 11-13 can consequently be generated, in order to switch off a current in the phase line. According to the embodiment example represented in FIG. 1, three switching modules are provided in each series connection. In general, the number of switching modules may be arbitrary and may have been adapted to the respective application. With a suitable number of switching modules that employ commercially available power semiconductors, voltages of up to 5 kV, for instance, can be switched off.

The alternating-current power switch 1 further includes a control device 4. The control device 4 is connected on the output side to each power-semiconductor switch of each switching module 21-29. The control device 4 is capable of switching each of the power-semiconductor switches on and off independently of one another. Hence the control device 4 is capable of driving the switching modules 21-29 in such a manner that predetermined switching-module voltages Us1-Us9, and hence also predetermined total voltages Ug1-Ug3, are generated at any time in each of the phase lines 31-33.

FIG. 2 shows the switching module 21 of the alternating-current power switch 1 shown in FIG. 1. The remaining switching modules 22-29 are of similar construction to switching module 21. Switching module 21 comprises four power-semiconductor switching units 41-44 and also an energy-storage device in the form of a power capacitor 40. Each power-semiconductor switching unit 41-44 exhibits a respective power semiconductor in the form of an IGBT 51-54 and a diode 61-64 antiparallel thereto.

Switching module 21 takes the form of a full-bridge circuit. By an appropriate drive of the individual power semiconductors 51-54, energy can be supplied to or withdrawn from the power capacitor 40. At the connectors or poles 71 and 72 of switching module 21 the voltage falling at the energy-storage device, also designated as the energy-storage voltage Ue, an oppositely-directed voltage −Ue or even a zero voltage can be set by suitable switching of the power semiconductors 51-54 on and/or off in a manner known to a person skilled in the art. With respect to further details of the structure and mode of operation of the converter 3 and of the full-bridge circuit, reference is hereby made, incidentally, to printed publication WO 2015/003737 A1.

The reversal of polarity of the voltage falling at the connectors 71, 72 can be obtained by alternating switching of the power-semiconductor pairs 51, 54 and 52, 53 on and off.

By suitable switching of the power semiconductors 51-54 on and off, over and above this the power capacitor 40 can be recharged in a manner known to a person skilled in the art prior to or in the course of a fall in voltage.

In normal operation of the alternating-current power switch 1 the power capacitor 40 is generally bypassed. This is done, for instance, by switching power semiconductor 51 or power semiconductor 52 on, depending on the direction of the operating current.

1-9. (canceled)

10. An alternating-current circuit breaker, comprising:
a series circuit of bipolar switching modules to be inserted in series into a phase line of an alternating-voltage line;
each said switching module having poles for carrying a switching module voltage, an energy-storage device and drivable power semiconductors capable of being switched on and off;
each said switching module being configured to be driven such that said poles carry a switching-module voltage that corresponds to a positive or negative energy-storage voltage or to a voltage having a zero value;
a control device connected to said switching modules, said control device being configured to drive said switching modules in dependence on a reversal of polarity of a phase current to cause the switching-module voltage to change a polarity thereof, enabling a switching-module voltage to be generated that is opposed to a phase voltage.

11. The alternating-current circuit breaker according to claim 10, wherein at least some of said switching modules are full-bridge circuits.

12. The alternating-current circuit breaker according to claim 10, wherein a sum of energy-storage voltages of said switching modules is greater than a product of a square root of two and a nominal voltage of the phase line.

13. The alternating-current circuit breaker according to claim 10, further comprising a monitoring device for monitoring energy-storage voltages of said switching modules, to enable a balancing of the energy-storage voltages.

14. A method for switching an alternating current, the method comprising:
providing an alternating-current circuit breaker with a series circuit of bipolar switching modules inserted in series into a phase line of an alternating-voltage line, each switching module having an energy-storage device and drivable power semiconductors that are capable of being switched on and off, and each switching module being enabled to be driven such that poles thereof generate a switching-module voltage that corresponds to a positive or negative energy-storage voltage or to a voltage having a value of zero;
using a control device for driving the switching modules; and
driving the switching modules in dependence on a reversal of polarity of a phase current such that the switching-module voltage changes a polarity and a switching-module voltage opposed to a phase voltage is generated.

15. The method according to claim 14, which comprises driving the switching modules concurrently upon a reversal of the polarity of the phase current, to cause the switching-module voltage to change polarity.

16. The method according to claim 14, which comprises driving the switching modules in a time-shifted manner upon a reversal of the polarity of the phase current, to cause the switching-module voltages to change polarity in time-shifted manner.

17. The method according to claim 14, which comprises providing switching modules being full-bridge circuits.

18. The method according to claim 14, which comprises monitoring the energy-storage voltages with a monitoring device for balancing the energy-storage voltages.
